(19) United States
(12) Patent Application Publication
(10) Pub. No.: US 2026/0058433 A1
(43) Pub. Date: Feb. 26, 2026

(54) Laser with Integrated Pattern Generation

(71) Applicant: ZEBRA TECHNOLOGIES CORPORATION, Lincolnshire, IL (US)

(72) Inventors: Chinh Tan, East Setauket, NY (US); Andrew Joseph Zosel, Blaine, WA (US)

(21) Appl. No.: 18/813,878

(22) Filed: Aug. 23, 2024

(51) Int. Cl. H01S 5/02257; H01S 5/02212; H04N 23/56

(52) U.S. Cl. CPC H01S 5/02257; H01S 5/02212

(57) ABSTRACT

Lasers with integrated pattern generation are provided herein. An example device includes a hermetically sealed housing having an optically transmissive window and a laser chip positioned within the housing and configured to emit light through the optically transmissive window, wherein the optically transmissive window includes an optical-pattern generating element configured to receive the light at a first surface and emit at least a portion of the light at a second surface opposite the first surface resulting in an optical pattern.

### BACKGROUND

Some applications of lasers involve optically manipulating a beam of a laser to project a pattern onto a surface. One such application, for example, is aiming pattern projection in imaging-based data capture devices. Laser aiming patterns improve the usability of imaging-based data capture devices by providing a user with a visual indication of where an object should be positioned so that the imaging-based data capture device may detect and decode data from the object. Unfortunately, existing methods of generating aiming patterns typically comprise several separate parts that must be assembled with tight tolerances and which occupy far more space than is ideal.

### SUMMARY

Devices which provide lasers with integrated pattern generation are provided herein. In an example embodiment, the present technology is a device comprising a laser diode, including a hermetically sealed housing having an optically transmissive window and a laser chip positioned within the housing and configured to emit light through the optically transmissive window, wherein the optically transmissive window includes an optical-pattern generating element configured to receive the light at a first surface and emit at least a portion of the light at a second surface opposite the first surface resulting in an optical pattern.

In a variation of this example embodiment, the first surface includes a collimating element.

In a variation of this example embodiment, the second surface includes a diffractive element.

In a variation of this example embodiment, the first or second surface includes an aperture configured to limit an amount of light passing through the optically transmissive window.

In a variation of this example embodiment, the optical-pattern generating element is adhered to the housing.

In a variation of this example embodiment, the optical-pattern generating element is directly affixed to the housing.

In a variation of this example embodiment, the laser diode is an edge emitting laser diode.

In a variation of this example embodiment, the laser diode produces red light with a wavelength between 600 nanometers (nm) and 690 nm.

In a variation of this example embodiment, the laser diode produces green light with a wavelength between 500 nanometers (nm) and 550 nm.

In a variation of this example embodiment, the housing has a first side including the optically transmissive window and a second side opposite the first side, wherein the second side has at least two conductors extending away from the housing and configured to be secured to a circuit board.

In a variation of this example embodiment, the at least two conductors include a first conductor, a second conductor, and a third conductor, wherein the first conductor is configured to supply a driving current to the laser chip, the second conductor is configured to supply a reference current indicative of a laser power, and the third conductor is configured as a structural component and electrical ground isolated from the other two conductors.

In a variation of this example embodiment, a height from a base of the housing to an exterior surface of the optically transmissive window does not exceed 6 milimeters excluding any protrusions from the exterior surface of the optically transmissive window.

In a variation of this example embodiment, the device includes an aperture which is an optically non-transmissive region.

In a variation of this example embodiment, the device includes an aperture which is a light-scattering region.

In another example embodiment, the present technology is an imaging-based data capture device including an imaging-based data capture device housing, an imaging assembly positioned within the housing and configured to capture image data over a field of view (FOV), and an aiming assembly configured to project an aiming pattern through an aperture of the imaging-based data capture device housing and into the FOV, wherein the aiming assembly includes a hermetically sealed housing having an optically transmissive window and a laser chip positioned within the housing and configured to emit light through the optically transmissive window, wherein the optically transmissive window includes an optical-pattern generating element configured to receive the light at a first surface and emit at least a portion of the light at a second surface opposite the first surface resulting in an optical pattern.

In a variation of this example embodiment, a total distance from a base of the imaging-based data capture device housing and the optically transmissive window is less than 9 millimeters.

In a variation of this example embodiment, the aiming assembly of the imaging-based data capture device includes no lens elements other than the optically transmissive window.

In a variation of this example embodiment, the imaging-based data capture device is an imaging engine configured to provide image data to a decoder module for decoding an indicium present in the image data.

### BRIEF DESCRIPTION OF THE DRAWINGS

The accompanying figures, where like reference numerals refer to identical or functionally similar elements throughout the separate views, together with the detailed description below, are incorporated in and form part of the specification, and serve to further illustrate embodiments of concepts that include the claimed technology, and explain various principles and advantages of those embodiments.

FIG. 1 illustrates an example laser with integrated pattern generation, according to example embodiments of the present disclosure.

FIG. 2 illustrates an example section view of an optically transmissive window, according to example embodiments of the present disclosure.

FIG. 3 illustrates an example top-down view of an optically transmissive window, according to example embodiments of the present disclosure.

FIG. 4 illustrates an example imaging-based data capture device projecting an aim pattern onto an object, according to example embodiments of the present disclosure.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present technology.

The apparatus and method components have been represented where appropriate by conventional symbols in the drawings, showing only those specific details that are pertinent to understanding the embodiments of the present technology so as not to obscure the disclosure with details that will be readily apparent to those of ordinary skill in the art having the benefit of the description herein.

### DETAILED DESCRIPTION

Devices of the present disclosure provide lasers with integrated pattern generation. Laser patterns are used in a variety of industries, often as a means to guide a user to position an object correctly for a device to perform some operation upon the object. For example, a circular saw might project a laser line onto wood about to be cut to give a user an indication of where the cut is about to occur. Typically, projecting a pattern with a laser involves employing one or more optical techniques to manipulate a beam of the laser into the pattern before the beam leaves the device. This can add significant complexity in design and assembly to devices which may otherwise be relatively simple. Using the example of the circular saw, optical elements such as lenses may be provided as part of a housing of the saw, requiring precise positioning of the laser relative to the housing and also requiring that any cavity within the housing be sealed to prevent intrusion by sawdust and other contaminants which might obscure the laser. It is therefore desirable to implement a laser device which does not require precise positioning relative to external optics and which does not require a housing of a larger device in which the laser device is placed to be sealed.

Devices of the present disclosure integrate the optics associated with pattern generation into a housing of the laser itself, rather than a device in which the laser is installed. Integrating pattern generating optics into the laser housing allows for much simpler final device assembly without adding much complexity to assembly of the laser. Integrating pattern generating optics also permanently sets positioning of a laser diode relative to the optics, thereby eliminating a need to test and adjust relative positioning of the laser diode and optics and making overall device calibration easier by allowing the laser diode and optics to be aimed as a unified entity.

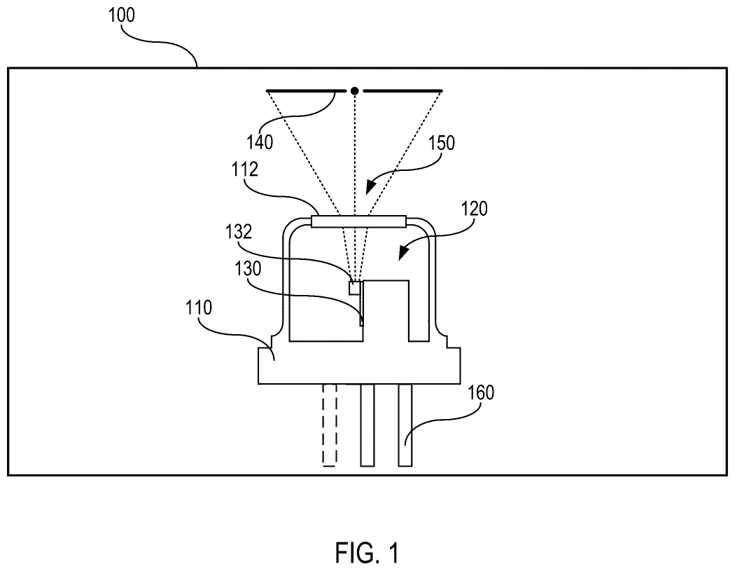

FIG. 1 illustrates an example laser 100 with integrated pattern generation, according to example embodiments of the present disclosure. In this example, a hermetically sealed housing 110 is provided enveloping a cavity 120 which contains a laser chip 130 (such as silicon submount). The hermetically sealed housing 110 includes an optically transmissive window 112 through which the edge emitting laser diode 132 is configured to emit light. A beam path 150 is illustrated along with a pattern 140 which the laser is configured to project onto a surface with which the beam path 150 intersects. The hermetically sealed housing 110 may be fashioned from any material, including but not limited to plastics, rubbers, ceramics, metals, wood, resins, composites, and combinations thereof. Though the hermetically sealed housing 110 is contemplated herein with a particular form factor, any geometry capable of maintaining a hermetically sealed chamber of sufficient size for the laser chip 130 may be employed.

Two or more electrical conductors 160 may be provided protruding from the hermetically sealed housing 110 as illustrated. The two or more electrical conductors may include a first conductor 160 configured to supply a driving current to the laser chip 130, a second conductor 160 configured to supply a reference current indicative of a laser power, and a third conductor configured to provide an electrical ground for the edge emitting laser diode and a laser power sensor. Each of these electrical conductors 160 may also serve a structural function, securing the laser 100 within a larger device and ensuring a consistent and reliable positioning and angle of the beam path 150. In some embodiments, the electrical conductors 160 may not protrude from the hermetically sealed housing 110 as through hole contacts (as is illustrated in FIG. 1), and may instead be integrated into the hermetically sealed housing 110 to implement a surface mount form factor. In these embodiments the electrical conductors 160 may still serve a structural purpose in addition to their electrical roles, securing the hermetically sealed housing 110 to pads on a circuit board rather than to holes through the circuit board.

The edge emitting laser diode 132 may emit light of any color or colors, including but not limited to green light (with a wavelength between 500 nanometers (nm) and 550 nm) and red light (with a wavelength between 600 nm and 690 nm). The edge emitting laser diode 132 may emit light of any intensity with a beam of any size. While contemplated herein as an edge emitting laser diode 132, it will be appreciated that other laser sources may be substituted for the edge emitting laser diode 132 including but not limited to surface emitting lasers, solid state lasers, gas lasers, chemical lasers, metal-vapor lasers, or any other device capable of emitting a focused beam of light. Additionally, some embodiments may provide two or more laser diodes 132, chips 130, and/or other laser sources within the hermetically sealed housing 110, and these laser sources need not be a same type of laser source (e.g. a laser diode 132 may be accompanied by a helium-neon laser) or emit a same wavelength or intensity of light.

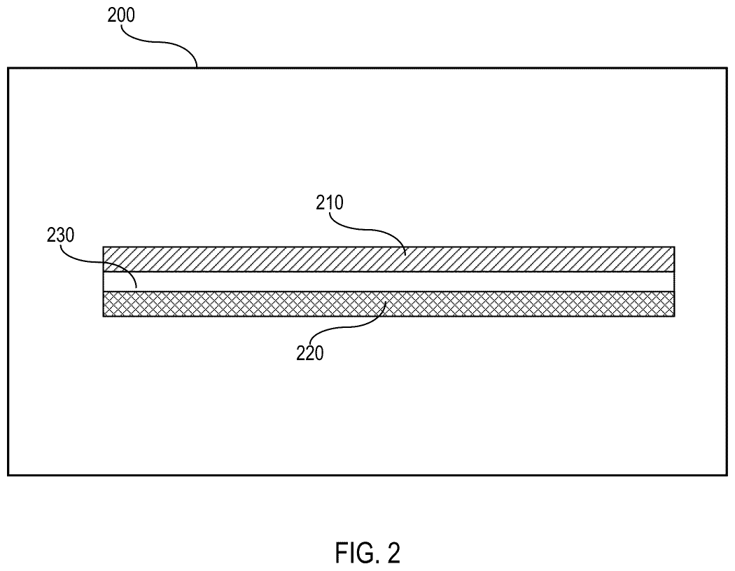

The optically transmissive window 112 may include a collimating element, an aperture, and/or a diffractive element (see FIG. 2). The optically transmissive window 112 may be affixed to the hermetically sealed housing 110 by means of adhesive, press fit, interference fit, plastic welding, molding, or any other technique for securing the optically transmissive window 112 to the hermetically sealed housing 110 such that a hermetic seal is preserved. The optically transmissive window 112 may be configured to focus, diffract, and/or regulate the beam path 150 as the laser diode 132 emits light through the optically transmissive window 112. While some space may exist between the laser chip 130 and the optically transmissive window 112 for optical purposes, a distance from an exterior surface of the optically transmissive window 112 to an exterior surface of the hermetically sealed housing 110 longitudinally opposed to the exterior surface of the optically transmissive window 112 along an axis of emission of the laser diode 132 may be less than 6 millimeters. The optically transmissive window 112 may be fashioned from any material, including but not limited to plastics, glasses, crystalline materials, composites, any other material which may transmit light and which may maintain a hermetic seal, and combinations thereof.

When in operation, an electrical current may be applied across the first conductor 160 and the third conductor 160. The electrical current may cause the laser diode 132 to begin emitting light which may enter a first surface on an interior of the optically transmissive window 112. The light may be focused, limited, and/or diffracted by varying elements of the optically transmissive window 112 before being projected out of a second surface on an exterior of the optically transmissive window 112 via the beam path 150 to form the pattern 140 on an external object which intersects the beam path 150. A light sensor (not illustrated) may receive a portion of reflected light which has been emitted by the laser diode 132 and may supply a current through the second conductor 160 and the third conductor 160, the magnitude of which may correspond with a power output of the laser diode 132.

FIG. 2 illustrates an example section view of an optically transmissive window 200, according to example embodiments of the present disclosure. In this example, a diffractive optical element 210, a collimating element 220, and a spacer layer 230 are stacked in a beam path of a laser diode (see FIG. 1) such that a beam of the laser diode enters the collimating element 220, passes through the spacer layer 230, and exits the diffractive optical element 210. In some embodiments, the spacer layer 230 may be omitted and an order of the collimating element 220 and the diffractive optical element 210 may be reversed. Additionally, some embodiments may provide more than one collimating element 220 and/or more than one diffractive optical element 210. In such embodiments, the collimating element(s) 220 and the diffractive optical element(s) may be placed in any order, and any number of spacer layers 230 may be provided between them.

The optically transmissive window 200 may be fashioned from any material or combination of materials capable of transmitting light and holding necessary geometries for implementing the collimating element 220 and the diffractive optical element 210. These materials may include but are not limited to plastics, glasses, resins, ceramics, crystalline materials, composites, and combinations thereof. The collimating element 220, the diffractive optical element 210, and the spacer layer 230 may be fashioned from a monolithic piece of material or may be laminated or otherwise affixed together to form the optically transmissive window 200. For example, the collimating element 220 and the optically diffractive element 210 may be etched or stamped into opposing sides of a glass disk. Alternatively, the collimating element 220 and the diffractive optical element 210 may, for example, be fashioned separately from plastic and adhered to opposing sides of a glass disk with clear adhesive or adhered or otherwise affixed directly to one another in the same manner.

The collimating element 220 may be any element capable of narrowing the laser beam, including but not limited to a convex lens, a metalens, a Fresnel lens, a cylindrical lens, a gradient lens, and an axicon. Individuals of skill in the art will appreciate that each of the many options for implementing the collimating element 220 may impose differing inherent restrictions on a geometry of the optically transmissive window 200 and a device in which the optically transmissive window 200 is installed, particularly where a focal point of the collimating element 220 is of concern (such as may be the case for positioning the diffractive optical element 210 when generating certain patterns). In situations where multiple collimating elements 220 are present, differing types of collimating elements 220 may be employed, multiple of a same type may be employed, or combinations thereof may be employed. For example, a metalens and a Fresnel lens may be used together or two Fresnel lenses may be used.

The diffractive optical element 210 may be any element capable of changing a profile of the laser beam as the laser beam passes through the diffractive optical element 210. This may include but is not limited to beam splitters, beam shapers, diffraction gratings, pattern generators, and diffusers. Just as with the collimating element 220, scenarios where multiple diffractive optical elements 210 are provided may include differing types of diffractive optical element 220, multiple of a same type, or combinations thereof. For example, a beam splitter and a beam shaper may be used or two beam shapers may be used. It will be appreciated that a pass-through medium which does not visibly alter a pattern of optical light that passes through, such as a layer of clear glass or plastic with no lens geometry, would not qualify as a diffractive optical element 210 or a pattern generating element.

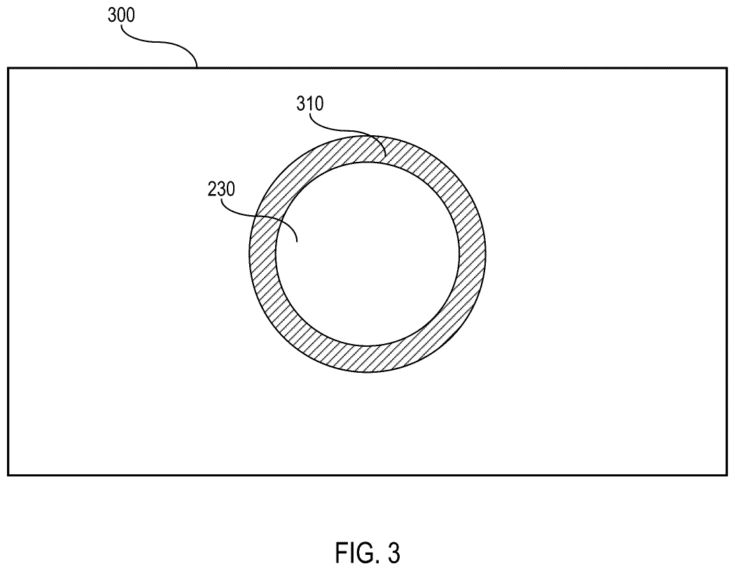

FIG. 3 illustrates an example top-down view of an optically transmissive window 300, according to example embodiments of the present disclosure. Particularly, a spacer layer 230 is depicted with an aperture defined by a light-blocking region 310. The light-blocking region 310 may be an optically non-transmissive region, such as an opaque or a reflective portion of the spacer layer 230, or may be a light-scattering region, such as a diffusing portion of the spacer layer 230. In some embodiments, the aperture may be included in the collimating element 220 or the diffractive optical element 210 instead of or in addition to the spacer layer 230. Some example embodiments may include multiple apertures, which may be of differing types (e.g. an optically non-transmissive light-blocking region 310 and a light-scattering light-blocking region 310) or of a same type (e.g. two optically non-transmissive light-blocking regions 310) or combinations thereof.

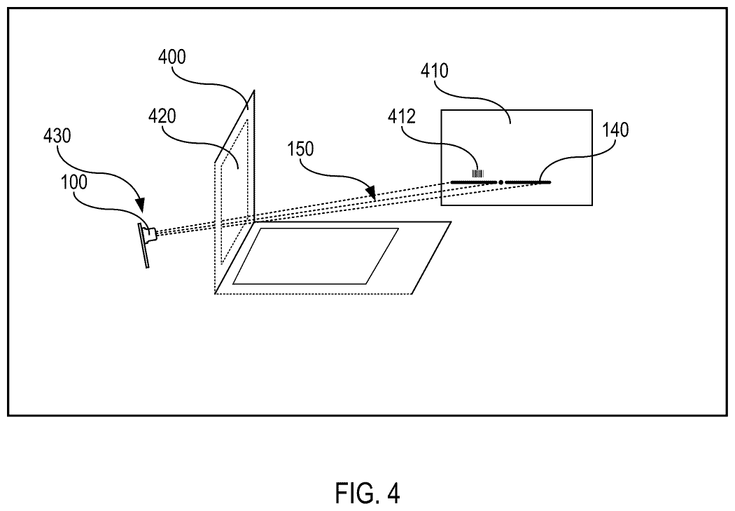

FIG. 4 illustrates an example imaging-based data capture device 400 projecting an aim pattern 140 onto an object 410, according to example embodiments of the present disclosure. In this example scenario, the imaging-based data capture device 400 is a barcode scanner which includes a vertical window 420 embedded in an imaging-based data capture device housing (only partially illustrated) and a laser 100 contained within the imaging-based data capture device housing. The object 410 is positioned such that a beam path 150 of the laser 100 which projects out of the imaging-based data capture device housing through the vertical window 420 intersects a surface of the object 410 and projects a pattern 140 onto the object 410. The laser 100 may be part of an aiming assembly 430 which includes other components designed to assist a user in correctly positioning the object 410 for data capture, such as additional lasers, displays, or indicator lights.

The pattern 140 may be positioned within a scanning region of the imaging-based data capture device 400 to help a user position the object 410 such that an indicium 412, for example the 1-D barcode illustrated herein, is appropriately positioned for the imaging-based data capture device 400 to decode a payload of the indicium 412. In some example scenarios, the laser 100 may be angle-adjustable to allow a technician to properly aim the pattern 140. It will be appreciated that this feature is a significant advantage of the technology of the present disclosure over existing techniques because changing an angle of the laser 100, which includes integrated optics for generating the pattern 140, is far less cumbersome and mechanically complex than implementing a mechanism within the aiming assembly 430 to change an angle of a laser and a separate optical assembly.

It will be appreciated that the imaging-based data capture device 400 need not be a barcode scanner and that the indicium 412 need not be a barcode. The imaging-based data capture device 400 may be any device which processes an image and extracts payload data from the image, including but not limited to the aforementioned barcode scanners, object recognition devices, facial recognition devices, fingerprint readers, optical character recognition devices, and gesture recognition devices. Likewise, the indicium 412 may be any marking on the object 410 which conveys a payload data to the imaging-based data capture device 400, including but not limited to 1-D barcodes, 2-D barcodes, alphanumeric or other linguistic characters, and patterns of colors.

The above description refers to a block diagram of the accompanying drawings. Alternative implementations of the example represented by the block diagram includes one or more additional or alternative elements, processes and/or devices. Additionally or alternatively, one or more of the example blocks of the diagram may be combined, divided, re-arranged or omitted. Components represented by the blocks of the diagram are implemented by hardware, software, firmware, and/or any combination of hardware, software and/or firmware. In some examples, at least one of the components represented by the blocks is implemented by a logic circuit. As used herein, the term “logic circuit” is expressly defined as a physical device including at least one hardware component configured (e.g., via operation in accordance with a predetermined configuration and/or via execution of stored machine-readable instructions) to control one or more machines and/or perform operations of one or more machines. Examples of a logic circuit include one or more processors, one or more coprocessors, one or more microprocessors, one or more controllers, one or more digital signal processors (DSPs), one or more application specific integrated circuits (ASICs), one or more field programmable gate arrays (FPGAs), one or more microcontroller units (MCUs), one or more hardware accelerators, one or more special-purpose computer chips, and one or more system-on-a-chip (SoC) devices. Some example logic circuits, such as ASICs or FPGAS, are specifically configured hardware for performing operations (e.g., one or more of the operations described herein and represented by the flowcharts of this disclosure, if such are present). Some example logic circuits are hardware that executes machine-readable instructions to perform operations (e.g., one or more of the operations described herein and represented by the flowcharts of this disclosure, if such are present). Some example logic circuits include a combination of specifically configured hardware and hardware that executes machine-readable instructions. The above description refers to various operations described herein and flowcharts that may be appended hereto to illustrate the flow of those operations. Any such flowcharts are representative of example methods disclosed herein. In some examples, the methods represented by the flowcharts implement the apparatus represented by the block diagrams. Alternative implementations of example methods disclosed herein may include additional or alternative operations. Further, operations of alternative implementations of the methods disclosed herein may combined, divided, re-arranged or omitted. In some examples, the operations described herein are implemented by machine-readable instructions (e.g., software and/or firmware) stored on a medium (e.g., a tangible machine-readable medium) for execution by one or more logic circuits (e.g., processor(s)). In some examples, the operations described herein are implemented by one or more configurations of one or more specifically designed logic circuits (e.g., ASIC(s)). In some examples the operations described herein are implemented by a combination of specifically designed logic circuit(s) and machine-readable instructions stored on a medium (e.g., a tangible machine-readable medium) for execution by logic circuit(s).

As used herein, each of the terms “tangible machine-readable medium,” “non-transitory machine-readable medium” and “machine-readable storage device” is expressly defined as a storage medium (e.g., a platter of a hard disk drive, a digital versatile disc, a compact disc, flash memory, read-only memory, random-access memory, etc.) on which machine-readable instructions (e.g., program code in the form of, for example, software and/or firmware) are stored for any suitable duration of time (e.g., permanently, for an extended period of time (e.g., while a program associated with the machine-readable instructions is executing), and/or a short period of time (e.g., while the machine-readable instructions are cached and/or during a buffering process)). Further, as used herein, each of the terms “tangible machine-readable medium,” “non-transitory machine-readable medium” and “machine-readable storage device” is expressly defined to exclude propagating signals. That is, as used in any claim of this patent, none of the terms “tangible machine-readable medium,” “non-transitory machine-readable medium,” and “machine-readable storage device” can be read to be implemented by a propagating signal.

In the foregoing specification, specific embodiments have been described. However, one of ordinary skill in the art appreciates that various modifications and changes can be made without departing from the scope of the technology as set forth in the claims below. Accordingly, the specification and figures are to be regarded in an illustrative rather than a restrictive sense, and all such modifications are intended to be included within the scope of present teachings. Additionally, the described embodiments/examples/implementations should not be interpreted as mutually exclusive, and should instead be understood as potentially combinable if such combinations are permissive in any way. In other words, any feature disclosed in any of the aforementioned embodiments/examples/implementations may be included in any of the other aforementioned embodiments/examples/implementations.

The benefits, advantages, solutions to problems, and any element(s) that may cause any benefit, advantage, or solution to occur or become more pronounced are not to be construed as a critical, required, or essential features or elements of any or all the claims. The claimed technology is defined solely by the appended claims including any amendments made during the pendency of this application and all equivalents of those claims as issued.

Moreover in this document, relational terms such as first and second, top and bottom, and the like may be used solely to distinguish one entity or action from another entity or action without necessarily requiring or implying any actual such relationship or order between such entities or actions. The terms “comprises,” “comprising,” “has”, “having,” “includes”, “including,” “contains”, “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a”, “has . . . a”, “includes . . . a”, “contains . . . a” does not, without more constraints, preclude the existence of additional identical elements in the process, method, article, or apparatus that comprises, has, includes, contains the element. The terms “a” and “an” are defined as one or more unless explicitly stated otherwise herein. The terms “substantially”, “essentially”, “approximately”, “about” or any other version thereof, are defined as being close to as understood by one of ordinary skill in the art, and in one non-limiting embodiment the term is defined to be within 10%, in another embodiment within 5%, in another embodiment within 1% and in another embodiment within 0.5%. The term “coupled” as used herein is defined as connected, although not necessarily directly and not necessarily mechanically. A device or structure that is “configured” in a certain way is configured in at least that way, but may also be configured in ways that are not listed.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter may lie in less than all features of a single disclosed embodiment. Thus, the following claims are hereby incorporated into the Detailed Description, with each claim standing on its own as a separately claimed subject matter.

What is claimed:

1. A device comprising a laser diode, including:
a hermetically sealed housing having an optically transmissive window; and
a laser chip positioned within the housing and configured to emit light through the optically transmissive window,
wherein the optically transmissive window includes an optical-pattern generating element configured to receive the light at a first surface and emit at least a portion of the light at a second surface opposite the first surface resulting in an optical pattern.

2. The device of claim 1, wherein the first surface includes a collimating element.

3. The device of claim 1, wherein the second surface includes a diffractive element.

4. The device of claim 1, wherein the first or second surface includes an aperture configured to limit an amount of light passing through the optically transmissive window.

5. The device of claim 1, wherein the optical-pattern generating element is adhered to the housing.

6. The device of claim 1, wherein the optical-pattern generating element is directly affixed to the housing.

7. The device of claim 1, wherein the laser diode is an edge emitting laser diode.

8. The device of claim 1, wherein the laser diode produces red light with a wavelength between 600 nanometers (nm) and 690 nm.

9. The device of claim 1, wherein the laser diode produces green light with a wavelength between 500 nanometers (nm) and 550 nm.

10. The device of claim 1, wherein the housing has a first side including the optically transmissive window and a second side opposite the first side, wherein the second side has at least two conductors extending away from the housing and configured to be secured to a circuit board.

11. The device of claim 10, wherein the at least two conductors include a first conductor, a second conductor, and a third conductor, wherein the first conductor is configured to supply a driving current to the laser chip, the second conductor is configured to supply a reference current indicative of a laser power, and the third conductor is configured as a structural component and electrical ground isolated from the other two conductors.

12. The device of claim 1, wherein a height from a base of the housing to an exterior surface of the optically transmissive window does not exceed 6 milimeters excluding any protrusions from the exterior surface of the optically transmissive window.

13. The device of claim 1, wherein the device includes an aperture which is an optically non-transmissive region.

14. The device of claim 1, wherein the device includes an aperture which is a light-scattering region.

15. An imaging-based data capture device including:
an imaging-based data capture device housing;
an imaging assembly positioned within the housing and configured to capture image data over a field of view (FOV); and
an aiming assembly configured to project an aiming pattern through an aperture of the imaging-based data capture device housing and into the FOV;
wherein the aiming assembly includes
a hermetically sealed housing having an optically transmissive window, and
a laser chip positioned within the housing and configured to emit light through the optically transmissive window,
wherein the optically transmissive window includes an optical-pattern generating element configured to receive the light at a first surface and emit at least a portion of the light at a second surface opposite the first surface resulting in an optical pattern.

16. The imaging-based data capture device of claim 15, wherein a total distance from a base of the imaging-based data capture device housing and the optically transmissive window is less than 9 millimeters.

17. The imaging-based data capture device of claim 15, wherein the aiming assembly of the imaging-based data capture device includes no lens elements other than the optically transmissive window.

18. The imaging-based data capture device of claim 15, wherein the imaging-based data capture device is an imaging engine configured to provide image data to a decoder module for decoding an indicium present in the image data.
